(19) United States
(12) Patent Application Publication
(10) Pub. No.: US 2008/0002479 A1
(43) Pub. Date: Jan. 3, 2008

(54) Data transfer system and data processing apparatus

(76) Inventor: Shinji Bito, Tokyo (JP)

Correspondence Address: MCDERMOTT WILL & EMERY LLP, 600 13TH STREET, NW, WASHINGTON, DC, 20005-3096, US

(21) Appl. No.: 11/802,304

(22) Filed: May 22, 2007

(30) Foreign Application Priority Data
May 22, 2006 (JP) P. 2006-141567

(51) Int. Cl. G11C 7/10

(52) U.S. Cl. 365/189.05

(57) ABSTRACT

The data transfer rate is enhanced without increasing the clock rate and the number of data signal lines, a data transfer system includes: a data transmitting section which transmits a second clock signal generated by frequency dividing a first clock signal, and a data signal including two bits for each cycle of the second clock signal; and a data receiving section which receives the second clock signal and the data signal, and which independently detects the two bits included in the data signal for each cycle of the second clock signal.

### BACKGROUND OF THE INVENTION

1. Field of the Invention

The present invention relates to a data transfer system and data processing apparatus in which the data transfer rate is enhanced.

2. Description of the Related Art

As third-generation portable telephones are popularized and the speed of the network is increased, data such as image data, motion picture data, and program data are required to be processed at a high speed. Accordingly, an operation clock rate of an LSI in a portable telephone is increased, or the number of data signal lines is increased, thereby increasing the data processing speed and the data transfer rate. According to the technique disclosed in JP-A-2004-7797, it is possible to attain high-speed transmission and low power consumption.

Patent Reference 1: JP-A-2004-7797

When the operation clock rate is increased, however, the power consumption of an LSI is increased. In an apparatus driven by a battery such as a mobile phone, the increase in power consumption results in a reduction of the operation time, and hence is not desirable. In addition, the increase in the number of data signal lines also undesirably results in an increase of an area of an LSI.

### SUMMARY OF THE INVENTION

It is an object of the invention to provide a data transfer system and data processing apparatus in which the data transfer rate is enhanced without increasing the clock rate and the number of data signal lines.

The invention provides a data transfer system comprising: a data transmitting section which transmits a second clock signal generated by frequency dividing a first clock signal, and a data signal including two bits for each cycle of the second clock signal; and a data receiving section which receives the second clock signal and the data signal, and which independently detects the two bits included in the data signal for each cycle of the second clock signal.

In the data transfer system, a clock frequency of the second clock signal is a half of a clock frequency of the first clock signal, and in the data signal transmitted from the data transmitting section, one bit is assigned to each of a HIGH period and a LOW period in one cycle of the second clock signal.

In the data transfer system, the data receiving section includes: a first system which detects one bit assigned to the HIGH period included in the data signal, for each cycle of the second clock signal; and a second system which detects one bit assigned to the LOW period included in the data signal for each cycle of the second clock signal.

In the data transfer system, the first system includes: a latching portion which latches the data signal in the HIGH period of the second clock signal; a first sampling portion which samples the data signal latched by the latching portion, at a timing of the second clock signal; and a first data detecting portion which detects data obtained by the first sampling portion, for each cycle of the second clock signal, and the second system includes: a second sampling portion which samples the data signal at the timing of the second clock signal; and a second data detecting portion which detects data obtained by the second sampling portion, for each cycle of the second clock signal.

In the data transfer system, the data signal is in a serial format.

In the data transfer system, the data signal is in a parallel format, and includes two sets of data of a data width number of the data signal, for each cycle of the second clock signal, and the data receiving section independently detects the two sets of data included in the data signal, for each cycle of the second clock signal.

The invention provides a data processing apparatus wherein the apparatus transmits a second clock signal generated by frequency dividing a first clock signal, and a data signal including two bits for each cycle of the second clock signal.

In the data processing apparatus, a clock frequency of the second clock signal is a half of a clock frequency of the first clock signal, and, in the data signal transmitted from the data transmitting section, one bit is assigned to each of a HIGH period and a LOW period in one cycle of the second clock signal.

In the data processing apparatus, the data signal is in a serial format.

In the data processing apparatus, the data signal is in a parallel format, and includes two sets of data of a data width number of the data signal, for each cycle of the second clock signal, and the apparatus independently detects the two sets of data included in the data signal, for each cycle of the second clock signal.

The invention provides a data processing apparatus wherein the apparatus receives a clock signal and a data signal including two bits for each cycle of the clock signal, and independently detects the two bits included in the data signal, for each cycle of the clock signal.

In the data processing apparatus, the apparatus comprises: a first system which detects one bit assigned to the HIGH period included in the data signal, for each cycle of the clock signal; and a second system which detects one bit assigned to the LOW period included in the data signal, for each cycle of the clock signal.

In the data processing apparatus, the first system includes: a latching portion which latches the data signal in the HIGH period of the clock signal; a first sampling portion which samples the data signal latched by the latching portion, at a timing of the clock signal; and a first data detecting portion which detects data obtained by the first sampling portion, for each cycle of the clock signal, and the second system includes: a second sampling portion which samples the data signal at the timing of the clock signal; and a second data detecting portion which detects data obtained by the second sampling portion, for each cycle of the clock signal.

In the data processing apparatus, the data signal is in a serial format.

In the data processing apparatus, the data signal is in a parallel format, and includes two sets of data of a data width number of the data signal, for each cycle of the clock signal, and the apparatus independently detects the two sets of data included in the data signal, for each cycle of the clock signal.

The invention provides a data processing apparatus comprising: a clock frequency dividing section which frequency divides a first clock signal to generate a second clock signal having a clock frequency that is a half of a clock frequency of the first clock signal; a high-speed processing section which outputs a data signal including two bits for each cycle of the second clock signal, based on the first clock signal; and a low-speed processing section which receives the second clock signal and the data signal, and which independently detects the two bits included in the data signal, for each cycle of the second clock signal.

In the data processing apparatus, in the data signal output from the high-speed processing section, one bit is assigned to each of a HIGH period and a LOW period in one cycle of the second clock signal.

In the data processing apparatus, the low-speed processing section includes: a first system which detects one bit assigned to the HIGH period included in the data signal, for each cycle of the second clock signal; and a second system which detects one bit assigned to the LOW period included in the data signal, for each cycle of the second clock signal.

In the data processing apparatus, the first system includes: a latching portion which latches the data signal in the HIGH period of the second clock signal; a first sampling portion which samples the data signal latched by the latching portion, at a timing of the second clock signal; and a first data detecting portion which detects data obtained by the first sampling portion, for each cycle of the second clock signal, and the second system includes: a second sampling portion which samples the data signal at the timing of the second clock signal; and a second data detecting portion which detects data obtained by the second sampling portion, for each cycle of the second clock signal.

In the data processing apparatus, the data signal is in a serial format.

In the data processing apparatus, the data signal is in a parallel format, and includes two sets of data of a data width number of the data signal, for each cycle of the second clock signal, and the low-speed processing section independently detects the two sets of data included in the data signal, for each cycle of the second clock signal.

According to the data transfer system and the data processing apparatus of the invention, the data transfer rate can be enhanced without increasing the clock rate and the number of data signal lines.

### BRIEF DESCRIPTION OF THE DRAWINGS

FIG. 1 is a block diagram showing the configuration of a data transfer system of a first embodiment.

FIG. 2 is a timing chart in the data transfer system of the first embodiment.

FIG. 3 is a block diagram showing the configuration of another example of the data transfer system of the first embodiment.

FIG. 4 is a block diagram showing the configuration of a data transfer system of a second embodiment.

FIG. 5 is a timing chart in the data transfer system of the second embodiment.

### DESCRIPTION OF THE PREFERRED EMBODIMENTS

Hereinafter, embodiments of the invention will be described with reference to the accompanying drawings.

### First Embodiment

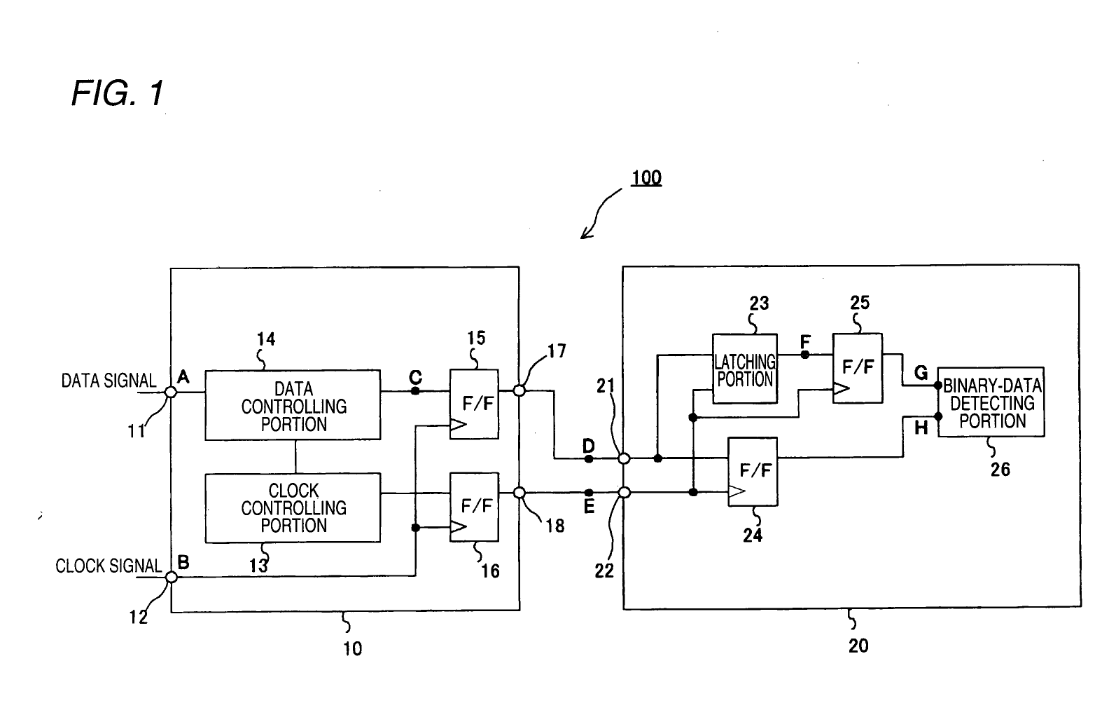

FIG. 1 is a block diagram showing the configuration of a data transfer system of a first embodiment. The data transfer system 100 of the first embodiment is a system for transferring serial data. As shown in FIG. 1, the system comprises a data transmitting section 10 and a data receiving section 20. The data transmitting section 10 transmits a serial data signal to the data receiving section 20. The data receiving section 20 receives the serial data signal.

The data transmitting section 10 includes input terminals 11, 12, a clock controlling portion 13, a data controlling portion 14, flip flops (hereinafter, referred to as “F/Fs”) 15, 16, and output terminals 17, 18.

A data signal is input to the input terminal 11. The data signal input through the input terminal 11 is input into the data controlling portion 14. A clock signal is input to the input terminal 12. The clock signal input through the input terminal 12 is input into the F/Fs 15, 16.

The clock controlling portion 13 sets the clock frequency of the clock signal output from the F/F 16. The clock controlling portion 13 has a function which is identical with that of a frequency divider. When the frequency dividing ratio set in the clock controlling portion 13 is “2”, for example, the F/F 16 outputs a clock signal having a clock frequency which is a half of that of the clock signal input through the input terminal 12, under the control of the clock controlling portion 13. Specifically, one cycle of the clock signal output from the F/F 16 includes two periods, i.e., a HIGH period corresponding to one cycle of the clock signal input through the input terminal 12, and a LOW period corresponding to one cycle of the clock signal input through the input terminal 12. The clock signal output from the F/F 16 is output through the output terminal 18.

The data controlling portion 14 adjusts the time length of one bit of the data signal input through the input terminal 11, to the length of a half cycle of the clock signal output from the F/F 16. When the frequency dividing ratio set in the clock controlling portion 13 is “2”, for example, the time length of one bit of the data signal output from the data controlling portion 14 is a half cycle of the clock signal output from the F/F 16, namely, the time length of one cycle of the clock signal input through the input terminal 12.

The data signal output from the data controlling portion 14 is input to the F/F 15. The F/F 15 samples the input data signal at the timing of the clock signal input through the input terminal 12. The F/F 15 outputs a serial data signal obtained by the sampling. The serial data signal output from the F/F 15 is output from the output terminal 17.

The data receiving section 20 has input terminals 21, 22, a latching portion 23, F/Fs 24, 25, and a binary-data detecting portion 26, and includes two systems. One of the systems is configured by the latching portion 23, the F/F 24, and the binary-data detecting portion 26. The other system is configured by the F/F 25 and the binary-data detecting portion 26.

To the input terminal 21, the serial data signal output through the output terminal 17 of the data transmitting section 10 is input. To the input terminal 22, the clock signal output from the output terminal 18 of the data transmitting section 10 is input. The serial data signal input through the input terminal 21, and the clock signal input through the input terminal 22 are input into the latching portion 23 and the F/F 24. The clock signal input through the input terminal 22 is input also into the F/F 25.

The latching portion 23 latches the serial data signal input through the input terminal 21 corresponding to the HIGH period of the clock signal input through the input terminal 22. The serial data signal output from the latching portion 23 is input into the F/F 25. The F/F 25 samples the serial data signal output from the latching portion 23, at the timing of the clock signal input through the input terminal 22. The F/F 25 outputs data obtained by the sampling. The data output from the F/F 25 is a serial data corresponding to the HIGH period of the clock signal. The serial data is input into the binary-data detecting portion 26.

The F/F 24 samples the serial data signal input through the input terminal 21, at the timing of the clock signal input through the input terminal 22. The F/F 24 outputs data obtained by the sampling. The data output from the F/F 24 is a serial data corresponding to the LOW period of the clock signal. The serial data is input into the binary-data detecting portion 26.

For each cycle of the clock signal input through the input terminal 22, the binary-data detecting portion 26 independently detects the two kinds of serial data, i.e., the serial data output from the F/F 25 corresponding to the HIGH period of the clock signal, and the serial data output from the F/F 24 corresponding to the LOW period of the clock signal. That is, the binary-data detecting portion 26 detects two bits, i.e., one bit in the HIGH period and one bit in the LOW period for each cycle of the clock signal.

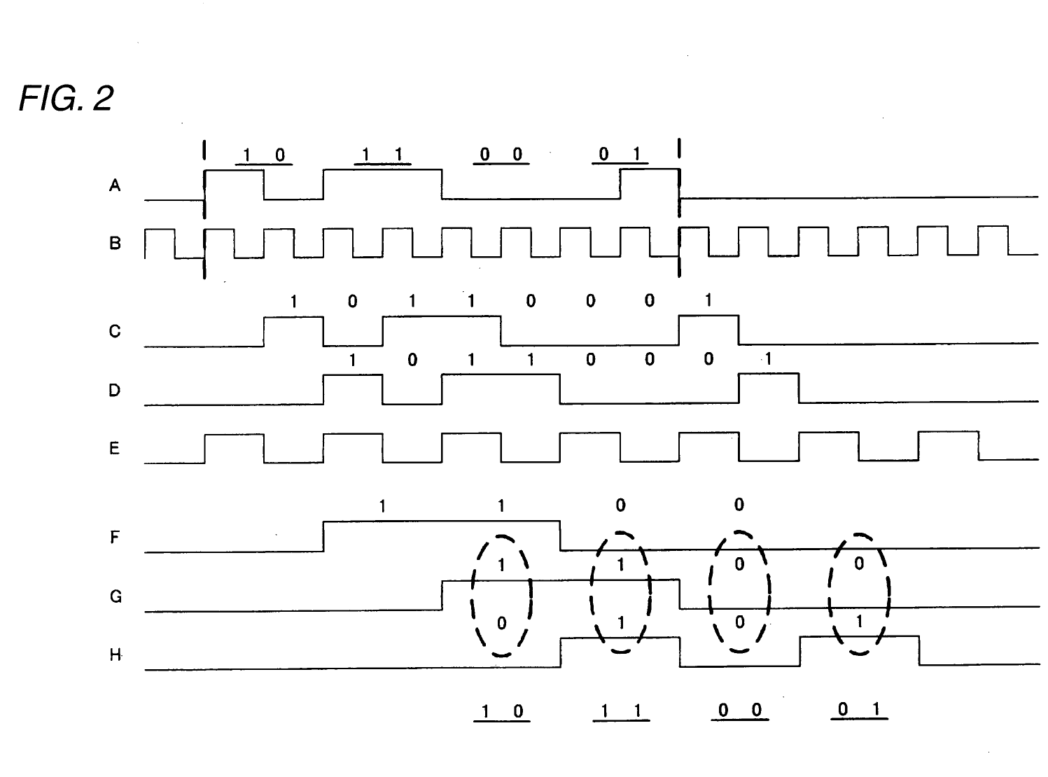

FIG. 2 is a timing chart in the data transfer system of the embodiment. The timing chart shows the case where the frequency dividing ratio set in the clock controlling portion 13 of the data transmitting section 10 is set to “2”.

In FIG. 2, “A” indicates the data signal input through the input terminal 11 of the data transmitting section 10. “B” indicates the clock signal input through the input terminal 12 of the data transmitting section 10. “C” indicates the data signal output from the data controlling portion 14 of the data transmitting section 10 and input into the F/F 15 of the data transmitting section 10. “D” indicates the serial data signal output from the output terminal 17 of the data transmitting section 10 and input into the input terminal 21 of the data receiving section 20. “E” indicates the clock signal output from the output terminal 18 of the data transmitting section 10 and input into the input terminal 22 of the data receiving section 20. “F” indicates the serial data signal output from the latching portion 23 of the data receiving section 20 and input into the F/F 25. “G” indicates the serial data signal corresponding to the HIGH period of the clock signal E, output from the F/F 25, and input into the binary-data detecting portion 26. “H” indicates the serial data signal corresponding to the LOW period of the clock signal E, output from the F/F 24, and input into the binary-data detecting portion 26.

As shown in the timing chart of FIG. 2, the value of the serial data signal G is the value of the serial data signal D in the HIGH period of the clock signal E. The value of the serial data signal H is the value of the serial data signal D in the LOW period of the clock signal E.

As described above, according to the data transfer system of the embodiment, the data transfer rate can be enhanced without increasing the clock rate of the clock signal B and the number of data signal lines.

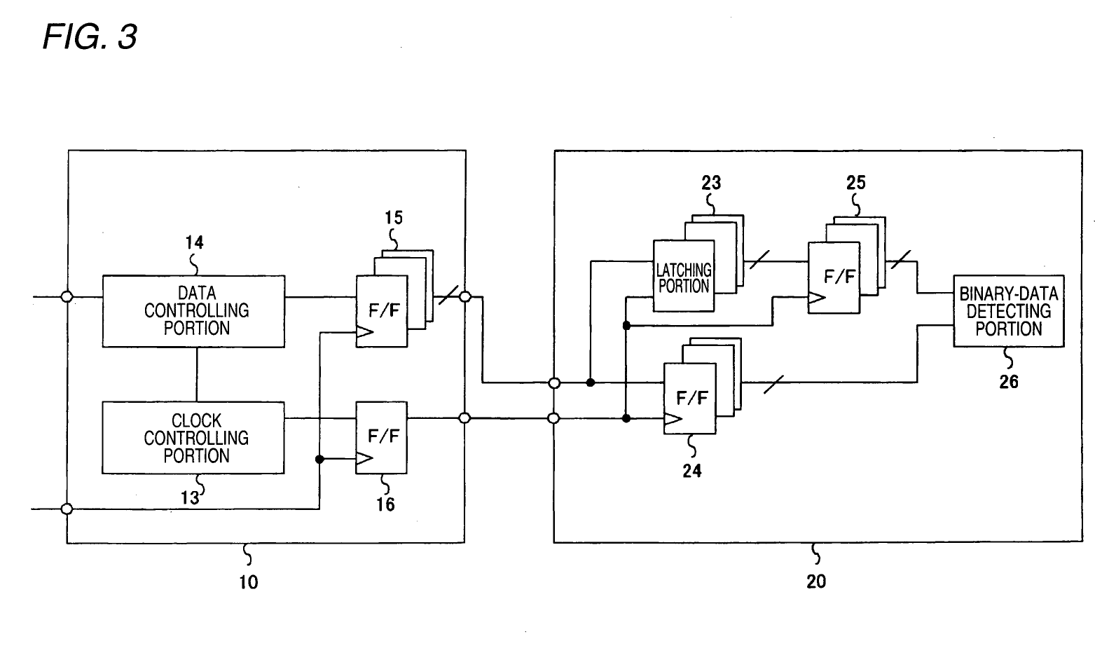

In the embodiment, the data transmitting section 10 and the data receiving section 20 process the serial data signal, but alternatively they may process a parallel data signal as shown in FIG. 3. In the alternative, the data controlling portion 14 of the data transmitting section 10 adjusts the time length of one bit of each data signal included in the parallel data signal, to a length which is equal to the half cycle of the clock signal output from the F/F 16. The F/F 15 of the data transmitting section 10, and the latching portion 23 and the F/Fs 24, 25 of the data receiving section 20 include F/Fs or latches the number of which is equal to that of the data width of the parallel data signal.

### Second Embodiment

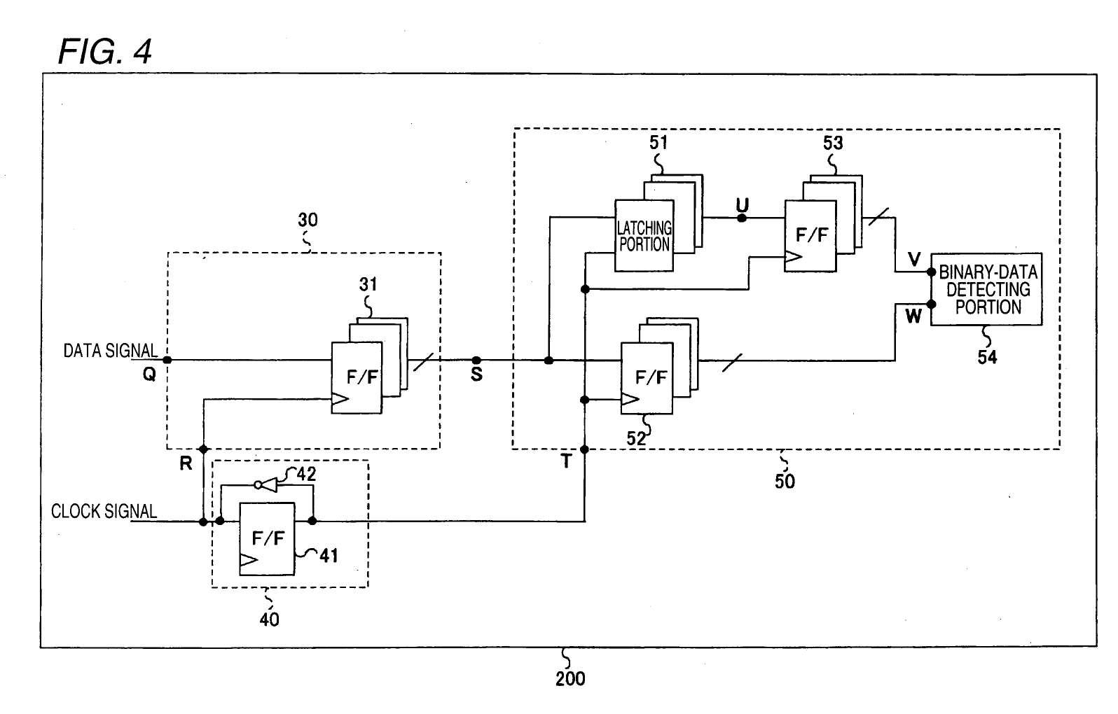

FIG. 4 is a block diagram showing the configuration of a data transfer system of a second embodiment. A data transfer system 200 of the second embodiment is a data processing apparatus disposed in an LSI. The system comprises a high-speed processing section 30, a clock frequency dividing section 40, and a low-speed processing section 50. A data signal processed in the high-speed processing section 30 is transferred to the low-speed processing section 50. In the embodiment shown in FIG. 4, the data signal is described as a data signal in a parallel format. Alternatively, the data signal may be in a serial format.

The high-speed processing section 30 outputs a parallel data signal input from the external, based on the clock signal supplied from the external. The high-speed processing section 30 includes F/Fs 31 the number of which is equal to that of the data width of the parallel data signal.

The clock frequency dividing section 40 includes an F/F 41 and an inverter 42, and generates a clock signal which is obtained by frequency dividing the clock signal supplied from the external by two. That is, the clock frequency dividing section 40 outputs a clock signal having a clock frequency which is a half of the clock frequency of the clock signal supplied from the external. Namely, one cycle of the clock signal output from the clock frequency dividing section 40 includes two periods, i.e., a HIGH period corresponding to one cycle of the clock signal supplied from the external, and a LOW period corresponding to one cycle of the clock signal supplied from the external.

The parallel data signal output from the high-speed processing section 30, and the clock signal output from the clock frequency dividing section 40 are input to the low-speed processing section 50. The low-speed processing section 50 has a latching portion 51, F/Fs 52, 53, and a binary-data detecting portion 54, and includes two systems. One of the systems is configured by the latching portion 51, the F/F 53, and the binary-data detecting portion 54. The other system is configured by the F/F 52 and the binary-data detecting portion 54. The parallel data signal input into the low-speed processing section 50 is input into the latching portion 51 and the F/F 52. The clock signal input into the low-speed processing section 50 is input into the latching portion 51, and the F/Fs 52, 53.

The latching portion 51 latches data signals of the parallel data signal corresponding to the HIGH period of the clock signal generated in the clock frequency dividing section 40. The parallel data signal output from the latching portion 51 is input into the F/F 53. The F/F 53 samples the parallel data signal output from the latching portion 51, at the timing of the clock signal generated in the clock frequency dividing section 40. The F/F 53 outputs data obtained by the sampling. The data output from the F/F 53 is parallel data corresponding to the HIGH period of the clock signal. The parallel data is input into the binary-data detecting portion 54.

The F/F 52 samples the parallel data signal at the timing of the clock signal generated in the clock frequency dividing section 40. The F/F 52 outputs data obtained by the sampling. The data output from the F/F 52 is a parallel data corresponding to the LOW period of the clock signal. The parallel data is input into the binary-data detecting portion 54.

For each cycle of the clock signal generated in the clock frequency dividing section 40, the binary-data detecting portion 54 independently detects two kinds of parallel data, i.e., the parallel data output from the F/F 53 corresponding to the HIGH period of the clock signal, and the parallel data output from the F/F 52 corresponding to the LOW period of the clock signal. That is, the binary-data detecting portion 54 detects two kinds of data, i.e., parallel data in the HIGH period and parallel data in the LOW period for each cycle of the clock signal.

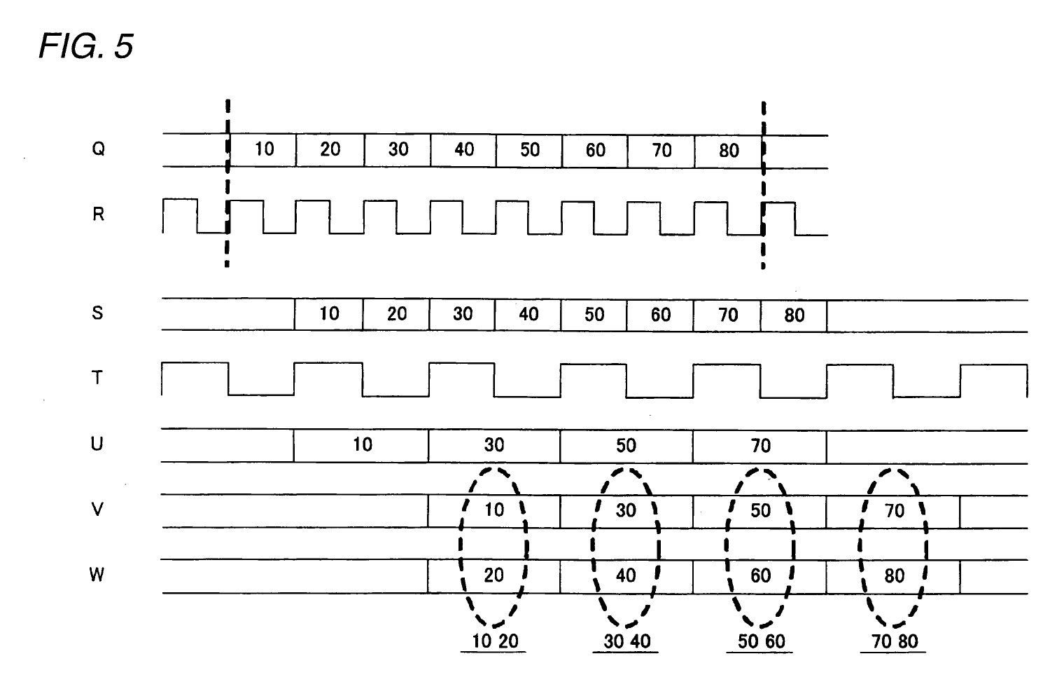

FIG. 5 is a timing chart in the data transfer system of the embodiment. In FIG. 5, “Q” indicates the data signal input into the high-speed processing section 30 from the external. “R” indicates the clock signal input into the high-speed processing section 30 from the external. “S” indicates the parallel data signal output from the high-speed processing section 30 and input into the low-speed processing section 50. “T” indicates the clock signal output from the clock frequency dividing section 40 and input into the low-speed processing section 50. “U” indicates the parallel data signal output from the latching portion 51 of the low-speed processing section 50, and input into the F/F 53. “V” indicates the parallel data signal corresponding to the HIGH period of the clock signal T, output from the F/F 53, and input into the binary-data detecting portion 54. “W” indicates the parallel data signal corresponding to the LOW period of the clock signal T, output from the F/F 52, and input into the binary-data detecting portion 54.

As shown in the timing chart of FIG. 5, the data of the parallel data signal V is the data of the parallel data signal S in the HIGH period of the clock signal T. The data of the parallel data signal W is the data of the parallel data signal S in the LOW period of the clock signal T.

As described above, according to the data transfer system of the embodiment, the data transfer rate can be enhanced without increasing the clock rate of the low-speed processing section 50 and the number of data signal lines.

The data transfer system and the data processing apparatus according to the invention do not involve the increases of the clock rate and the number of data signal lines, and are useful as a system, apparatus, and the like which require a high data transfer rate.

What is claimed is:

1. A data transfer system, comprising:
a data transmitting section which transmits a second clock signal generated by frequency dividing a first clock signal, and a data signal including two bits for each cycle of said second clock signal; and
a data receiving section which receives said second clock signal and said data signal, and which independently detects the two bits included in said data signal for each cycle of said second clock signal.

2. The data transfer system according to claim 1, wherein
a clock frequency of said second clock signal is a half of a clock frequency of said first clock signal, and
in said data signal transmitted from said data transmitting section, one bit is assigned to each of a HIGH period and a LOW period in one cycle of said second clock signal.

3. The data transfer system according to claim 2, wherein
said data receiving section includes:
a first system which detects one bit assigned to the HIGH period included in said data signal, for each cycle of said second clock signal; and
a second system which detects one bit assigned to the LOW period included in said data signal for each cycle of said second clock signal.

4. The data transfer system according to claim 3, wherein
said first system includes:
a latching portion which latches said data signal in the HIGH period of said second clock signal;
a first sampling portion which samples said data signal latched by said latching portion, at a timing of said second clock signal; and
a first data detecting portion which detects data obtained by said first sampling portion, for each cycle of said second clock signal, and
said second system includes:
a second sampling portion which samples said data signal at the timing of said second clock signal; and
a second data detecting portion which detects data obtained by said second sampling portion, for each cycle of said second clock signal.

5. The data transfer system according to claim 1, wherein
said data signal is in a serial format.

6. The data transfer system according to claim 1, wherein
said data signal is in a parallel format, and includes two sets of data of a data width number of said data signal, for each cycle of said second clock signal, and
said data receiving section independently detects said two sets of data included in said data signal, for each cycle of said second clock signal.

7. A data processing apparatus wherein said apparatus transmits a second clock signal generated by frequency dividing a first clock signal, and a data signal including two bits for each cycle of said second clock signal.

8. The data processing apparatus according to claim 7, wherein
a clock frequency of said second clock signal is a half of a clock frequency of said first clock signal, and
in said data signal transmitted from said data transmitting section, one bit is assigned to each of a HIGH period and a LOW period in one cycle of said second clock signal.

9. The data processing apparatus according to claim 7, wherein
said data signal is in a serial format.

10. The data processing apparatus according to claim 7, wherein
said data signal is in a parallel format, and includes two sets of data of a data width number of said data signal, for each cycle of said second clock signal, and
said apparatus independently detects said two sets of data included in said data signal, for each cycle of said second clock signal.

11. A data processing apparatus wherein said apparatus receives a clock signal and a data signal including two bits for each cycle of said clock signal, and independently detects the two bits included in said data signal, for each cycle of said clock signal.

12. The data processing apparatus according to claim 11, wherein said apparatus comprises:
a first system which detects one bit assigned to the HIGH period included in said data signal, for each cycle of said clock signal; and
a second system which detects one bit assigned to the LOW period included in said data signal, for each cycle of said clock signal.

13. The data processing apparatus according to claim 12, wherein
said first system includes:
a latching portion which latches said data signal in the HIGH period of said clock signal;
a first sampling portion which samples said data signal latched by said latching portion, at a timing of said clock signal; and
a first data detecting portion which detects data obtained by said first sampling portion, for each cycle of said clock signal, and
said second system includes:
a second sampling portion which samples said data signal at the timing of said clock signal; and
a second data detecting portion which detects data obtained by said second sampling portion, for each cycle of said clock signal.

14. The data processing apparatus according to claim 11, wherein
said data signal is in a serial format.

15. The data processing apparatus according to claim 11, wherein
said data signal is in a parallel format, and includes two sets of data of a data width number of said data signal, for each cycle of said clock signal, and
said apparatus independently detects said two sets of data included in said data signal, for each cycle of said clock signal.

16. A data processing apparatus comprising:
a clock frequency dividing section which frequency divides a first clock signal to generate a second clock signal having a clock frequency that is a half of a clock frequency of said first clock signal;
a high-speed processing section which outputs a data signal including two bits for each cycle of said second clock signal, based on said first clock signal; and
a low-speed processing section which receives said second clock signal and said data signal, and which independently detects the two bits included in said data signal, for each cycle of said second clock signal.

17. The data processing apparatus according to claim 16, wherein
in said data signal output from said high-speed processing section, one bit is assigned to each of a HIGH period and a LOW period in one cycle of said second clock signal.

18. The data processing apparatus according to claim 17, wherein
said low-speed processing section includes:
a first system which detects one bit assigned to the HIGH period included in said data signal, for each cycle of said second clock signal; and
a second system which detects one bit assigned to the LOW period included in said data signal, for each cycle of said second clock signal.

19. The data processing apparatus according to claim 18, wherein
said first system includes:
a latching portion which latches said data signal in the HIGH period of said second clock signal;
a first sampling portion which samples said data signal latched by said latching portion, at a timing of said second clock signal; and
a first data detecting portion which detects data obtained by said first sampling portion, for each cycle of said second clock signal, and
said second system includes:
a second sampling portion which samples said data signal at the timing of said second clock signal; and
a second data detecting portion which detects data obtained by said second sampling portion, for each cycle of said second clock signal.

20. The data processing apparatus according to claim 16, wherein
said data signal is in a serial format.

21. The data processing apparatus according to claim 16, wherein
said data signal is in a parallel format, and includes two sets of data of a data width number of said data signal, for each cycle of said second clock signal, and
said low-speed processing section independently detects said two sets of data included in said data signal, for each cycle of said second clock signal.
